(19) United States
(12) Patent Application Publication
(10) Pub. No.: US 2022/0291551 A1
(43) Pub. Date: Sep. 15, 2022

(54) WAVELENGTH CONVERSION MATERIAL, LIGHT-EMITTING DEVICE AND DISPLAY DEVICE

(71) Applicant: Lextar Electronics Corporation, Hsinchu (TW)

(72) Inventors: Yi-Ting TSAI, Hsinchu (TW); Hung-Chia WANG, Hsinchu (TW); Chia-Chun HSIEH, Hsinchu (TW); Pei-Cong YAN, Hsinchu (TW); Hung-Chun TONG, Hsinchu (TW); Yu-Chun LEE, Hsinchu (TW); Tzong-Liang TSAI, Hsinchu (TW)

(21) Appl. No.: 17/650,856

(22) Filed: Feb. 14, 2022

(30) Foreign Application Priority Data
Mar. 10, 2021 (CN) 202110259425.4

(51) Int. Cl. G02F 1/1335; G02F 1/13357

(52) U.S. Cl. CPC G02F 1/133614; G02F 1/133603

(57) ABSTRACT

A wavelength conversion material comprises a luminous core and a covering layer. The luminous core comprises a quantum dot or a fluorescent powder. The covering layer covers the luminous core. The covering layer is an amorphous material, and an outer surface of the covering layer has at least one sharp corner.

### CROSS-REFERENCE TO RELATED APPLICATION

This application claims priority to China Application Serial Number 202110259425.4, filed Mar. 10, 2021, which is herein incorporated by reference in its entirety.

### BACKGROUND

### Field of Invention

The present disclosure relates to a wavelength conversion material, a light-emitting device and a display device.

### Description of Related Art

In recent years, backlight displays have been developed rapidly, and applications of liquid crystal displays (LCD) have gradually become popular. So far, LCD application has progressed into the field of mini light-emitting diode (LED) and micro LED. As the sizes of LED become smaller, the sizes of light-emitting materials (such as quantum dot) also decrease. Quantum dots gradually become a popular research topic. Quantum dots, as nanoscale light-emitting materials, take advantage of narrow spectrum and high color purity. When dispersing in the adhesive, the dispersion of quantum dots may affect flowability and operability of the adhesive.

### SUMMARY

An aspect of the disclosure is to provide a light conversion material which can effectively solve the aforementioned problems.

According to an embodiment of the present disclosure, a wavelength conversion material comprises a luminous core and a covering layer. The luminous core comprises a quantum dot or a fluorescent powder. The covering layer covers the luminous core. The covering layer is an amorphous material, and an outer surface of the covering layer has at least one sharp corner.

According to an embodiment of the present disclosure, the amorphous material is a dielectric material.

According to an embodiment of the present disclosure, the covering layer is a non-luminous material.

According to an embodiment of the present disclosure, the covering layer is a non-metal material.

According to an embodiment of the present disclosure, the covering layer is an integrally-formed structure.

According to an embodiment of the present disclosure, the covering layer is substantially transparent.

According to an embodiment of the present disclosure, the outer surface of the covering layer further comprises a first concave portion and a second concave portion. The first concave portion and the second concave portion together define the sharp corner.

According to an embodiment of the present disclosure, a diameter of the luminous core is in a range from 15 nm to 25 nm.

According to an embodiment of the present disclosure, a light-emitting device comprises a substrate, a light-emitting diode, a transparent material and a plurality of the wavelength conversion materials. The light-emitting diode is on the substrate. The transparent material covers the light-emitting diode. The wavelength conversion materials are dispersed in the transparent material.

According to an embodiment of the present disclosure, a display device comprises a carrier substrate and a plurality of the light-emitting device. The light-emitting devices are arranged on the carrier substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A illustrates the wavelength conversion material before grinding in accordance with some embodiments of the present disclosure.

FIGS. 1B-1E illustrates wavelength conversion materials after grinding in accordance with some embodiments of the present disclosure.

FIG. 2 illustrates a flow chart of grinding the wavelength conversion materials in accordance with some embodiments of the present disclosure.

FIG. 3 illustrates a light-emitting device using the wavelength conversion materials in accordance with some embodiments of the present disclosure.

FIG. 4 illustrates a light-emitting device using the wavelength conversion materials in accordance with some embodiments of the present disclosure.

FIG. 5 illustrates a display device using the wavelength conversion materials in accordance with some embodiments of the present disclosure.

FIGS. 6-7 illustrate TEM (Transmission Electron Microscopy) images of the grinded wavelength conversion materials under different magnifications in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “in some embodiments” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

Some embodiments of the present disclosure may improve the stability of the wavelength conversion materials. More particularly, when grinding the wavelength conversion materials, additives with different composition may be added to grind the wavelength conversion materials, which may increase the dispersion of the wavelength conversion materials in the adhesive, thereby improving the stability of the LED device.

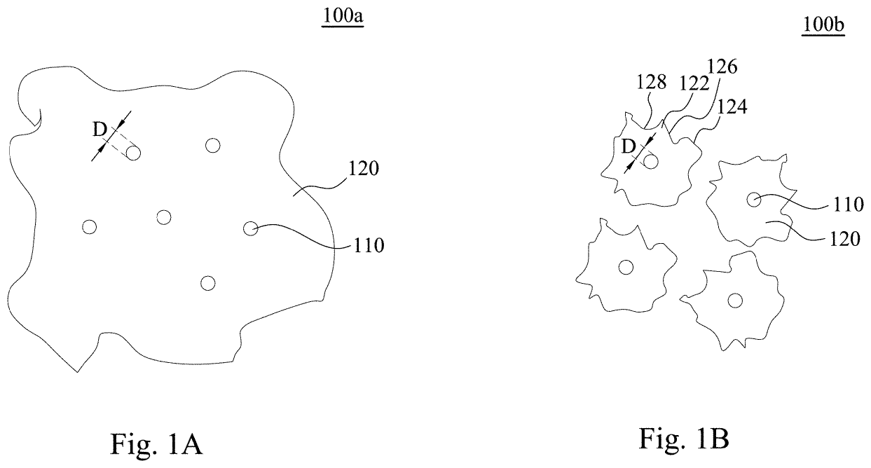

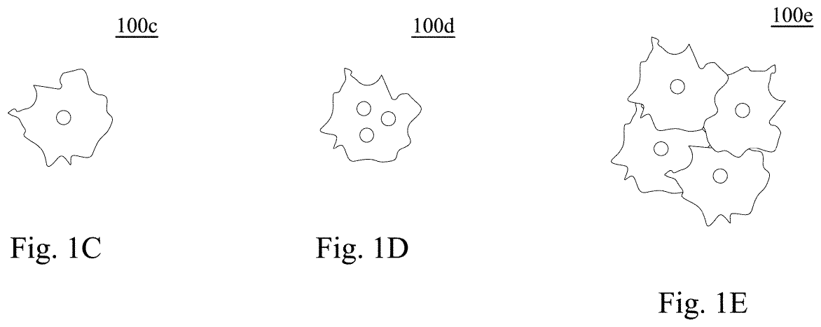

FIG. 1A illustrates the wavelength conversion material 100a before grinding in accordance with some embodiments of the present disclosure. The wavelength conversion material 100a includes luminous cores 110 and a covering layer 120. The wavelength conversion material 100a may convert the wavelength of light, for example, converting the light with the first wavelength to the light with the second wavelength. In some embodiments, the wavelength conversion material 100a may convert blue light (such as wavelength in a range from about 445 nm to about 470 nm) to green light (such as wavelength in a range from about 500 nm to about 540 nm). In some other embodiments, the wavelength conversion material 100a may convert blue light to red light (such as wavelength in a range from about 610 nm to about 700 nm). If the wavelength conversion materials 100a are placed in a display device, various lights emitted from LED are converted to different lights, such as red light, green light or blue light, based on different situations.

FIG. 1B illustrates grinded wavelength conversion materials 100b in accordance with some embodiments of the present disclosure. Generally speaking, after grinding the wavelength conversion material 100a in FIG. 1A, the wavelength conversion material 100a like a bulk in FIG. 1A is grinded into smaller pieces shown in FIG. 1B and becomes wavelength conversion materials 100b. At this moment, the number of luminous cores 110 included in the wavelength conversion materials 100b is less than the wavelength conversion material 100a. The wavelength conversion material 100a may include multiple luminous cores 110, as shown in FIG. 1A, while the wavelength conversion material 100b includes single luminous core 110 (as shown in FIGS. 1B, 1C and 1E) or few luminous cores 110 (as shown in FIG. 1D). The luminous cores 110 are nanoscale light-emitting materials, such as quantum dots, fluorescent powders or in any other suitable forms. In some embodiments, the diameter D of the luminous cores 110 is in a range from about 15 nm to about 25 nm.

In some embodiments, quantum dot materials of the luminous cores 110 include CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, CsPbX₃ or Cs₄PbX₆, wherein X is CI, Br, I or combinations thereof.

In some embodiments, materials of the fluorescent powders of the luminous cores 110 include Y₃Al₅O₁₂(YAG), LuYAG, GaYAG, SrS:Eu²⁺, SrGa₂S₄:Eu²⁺, ZnS:Cu⁺, ZnS:Ag⁺, Y₂O₂S:Eu²⁺, La₂O₂S:Eu²⁺, Gd₂O₂S:Eu²⁺, SrGa₂S₄:Ce³⁺, ZnS:Mn²⁺, SrS:Eu²⁺, CaS:Eu²⁺, (Sr₁₋ₓCaₓ)S:Eu²⁺, Ba₂SiO₄:Eu²⁺, Sr₂SiO₄:Eu²⁺, (Mg, Ca, Sr, Ba)₃Si₂O₇:Eu²⁺, Ca₈Mg(SiO₄)₄Cl₂:Eu²⁺, (Mg,Ca,Sr,Ba)₂SiO₄:Eu²⁺, (Sr,Ca,Ba)SiₓO_{y}N_{z}:Eu²⁺, (Ca,Mg,Y)Si_{w}AlₓO_{y}N_{z}:Ce²⁺, Ca₂Si₅N₈:Eu²⁺, (Ca,Mg,Y)Si_{w}AlₓO_{y}N_{z}:Eu²⁺, K₂GeF₆:Mn⁴⁺, K₂SiF₆:Mn⁴⁺, K₂TiF₆:Mn⁴⁺, Sr(LiAl₃N₄):Eu²⁺, Si₆₋ₙAlₙOₙN₈₋ₙ (n=0-4.2):Eu²⁺ or combinations thereof.

A covering layer 120 wraps around multiple luminous cores 110 and is used to modify the surfaces of the luminous cores 110 to improve light/thermal stability or other properties of the luminous cores 110. The covering layer is also used to prevent the luminous cores 110 from damage from substances in the environment (such as damage from oxygen and water vapor), so that the luminous cores 110 have good light-emitting lifetime.

In some embodiments, the covering layer 120 may be made of any suitable amorphous materials. Amorphous materials don't have grain boundaries which crystalline materials may have. The grain boundaries may extend to the outer surface 124 of the covering layer 120 and serve as a path for oxygen or water vapor to penetrate into the luminous cores 110. Therefore, the covering layer 120 made of amorphous materials may have good coverability, providing a good protection for the luminous cores 110.

In some embodiments, amorphous materials may be non-metal materials or dielectric materials, such as oxide (such as SiO₂) or other suitable materials. Further, in some embodiments, the covering layer 120 may be made of only single material; thus no interfaces or no obvious interfaces exist in the covering layer 120. That is, the covering layer 120 may be integrally-formed. As discussed above, the covering layer 120 has no (obvious) interfaces, which may become the path for oxygen or water vapor to penetrate into the luminous cores 110, therefore the covering layer 120 may have good coverability, providing a good protection for the luminous cores 110.

In some embodiments, the covering layer 120 may be non-luminous materials; that is, the covering layer 120 is unable to emit light. Alternatively, the color of emitting light of the wavelength conversion materials 100b depends on the luminous core 110, which means that the color of light emitted from the luminous core 110 itself is substantially the same as the color of light emitted from the wavelength conversion materials 100b. In addition, the intensity of light emitted from the wavelength conversion materials 100b is slightly lower than (or not higher than) the intensity of light emitted from the luminous core 110 itself.

The term “substantially” as used herein may be applied to modify any quantitative representation which could permissibly vary without resulting in a change in the basic function to which it is related. Take the description “the color of light emitted from the luminous core 110 itself is substantially same as the color of light emitted from the wavelength conversion materials 100b” as an example, the description means that compared to the color of light emitted from the wavelength conversion materials 100b, the color of light emitted from the luminous core 110 itself is exactly the same. In addition, the covering layer 120 itself also has a color as long as the color of light emitted from the luminous core 110 doesn't change. In this case, the color of the light emitted from the luminous core 110 itself and the color of light emitted from the wavelength conversion materials 100b are substantially the same as long as the wavelength difference between the color of light emitted from the luminous core 110 itself and the color of light emitted from the wavelength conversion materials 100b is less than 20 nm.

In some embodiments, the covering layer 120 may be substantially transparent. For example, the transmittance of the covering layer 120 is in a range from about 90% to about 100%, or about 95% to about 100%, or about 99% to about 100%. Therefore, the covering layer 120 does not affect (or does not significantly reduce) the intensity of light emitted from the luminous core 110.

Compared to the smooth outer surface of the wavelength conversion material 100a, the grinded wavelength conversion materials 100b have an outer surface 124 with multiple sharp corners 122. These sharp corners 122 are together defined by different concave portions, for example, together defined by first concave portions 126 and second concave portions 128. The first concave portions 126 and the second concave portions 128 are concave towards the luminous core 110. In some embodiments, the sharp corner defined by the first concave portion 126 and the second concave portion 128 has an acute angle (less than 90°).

In addition to FIG. 1B, the grinded wavelength conversion materials 100b may also be in the form of the wavelength conversion materials 100c, 100d and 100e as shown in FIGS. 1C-1E. In FIG. 1C, each of the wavelength conversion materials 100c has a single luminous core 110 in the internal part thereof. In FIG. 1D, each of the wavelength conversion materials 100d has multiple luminous cores 110 in the internal part thereof. It is noted that although FIG. 1D illustrates 3 luminous cores in the wavelength conversion material 100d, the number of the wavelength conversion materials 100d may be less or more, such as 2 or 4. In FIG. 1E, a wavelength conversion material 100e, which is aggregated by the wavelength conversion materials 100c in FIG. 1C, is illustrated in FIG. 1E. In other words, a wavelength conversion material 100e includes a plurality of the wavelength conversion materials 100c. In FIGS. 1C-1E, the outer surface 124 of each of the wavelength conversion materials 100c, 100d and 100e has at least one sharp corner 122, and this sharp corner 122 is together defined by two concave portions. Other characteristics of the wavelength conversion materials 100c, 100d and 100e are the same as or similar to the wavelength conversion materials 100b and are not mentioned here repeatedly.

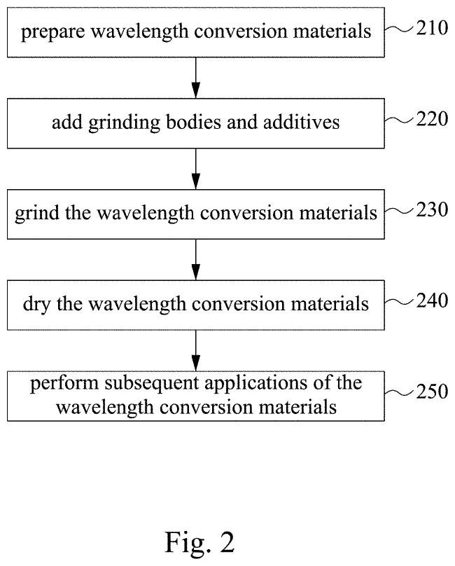

FIG. 2 illustrates a flow chart of grinding the wavelength conversion materials 100a in accordance with some embodiments of the present disclosure. In operation 210, wavelength conversion materials are prepared. More specifically, wavelength conversion materials 100a as shown in FIG. 1A may be prepared and placed into a grinding apparatus for grinding. As shown in FIG. 1A, outer surfaces of the wavelength conversion materials 100a before grinding are smooth convex surfaces, and each of the wavelength conversion materials 100a includes multiple (such as more than 5) luminous cores 110. The wavelength conversion materials 100a undergo a grinding process to disperse the luminous cores 110.

In operation 220, grinding bodies and additives are added. The grinding bodies may be any suitable solid matter to grind the wavelength conversion materials 100a into pieces and have any suitable shapes, such as spheres, cubes, or the like. In some embodiments, grinding bodies may be zirconium beads, stainless steel balls, the like, or combinations thereof. Some additives may be added when grinding the wavelength conversion materials 100a. In addition, additives may include a specific mixture. The specific mixture may be a mixture of phosphates, alcohols functional groups (—OH) or combinations thereof. For example, the additives may be made of isopropanol, n-butanol, sodium tripolyphosphate, sodium hexametaphosphate, sodium pyrophosphate, etc. added in ethanol. Further, the specific mixture is in a trace amount compared to the amount of ethanol. In some embodiments, the specific mixture is about 0.01 vol % to about 1 vol % of ethanol. Characteristics of high static electricity and aggregation of the grinded wavelength conversion materials 100b may be reduced by using the additives including the mixture discussed above, thereby increasing dispersion of the grinded wavelength conversion materials 100b in the adhesive materials (such as packaging adhesive) or plate materials.

In some embodiments, the total volume of the additives is about 0.1 vol % to about 5 vol % of the total volume of the grinding bodies. If the total volume of the additives is out of this range, it is found that the grinded wavelength conversion materials 100b may not be dispersed effectively according to experiment results.

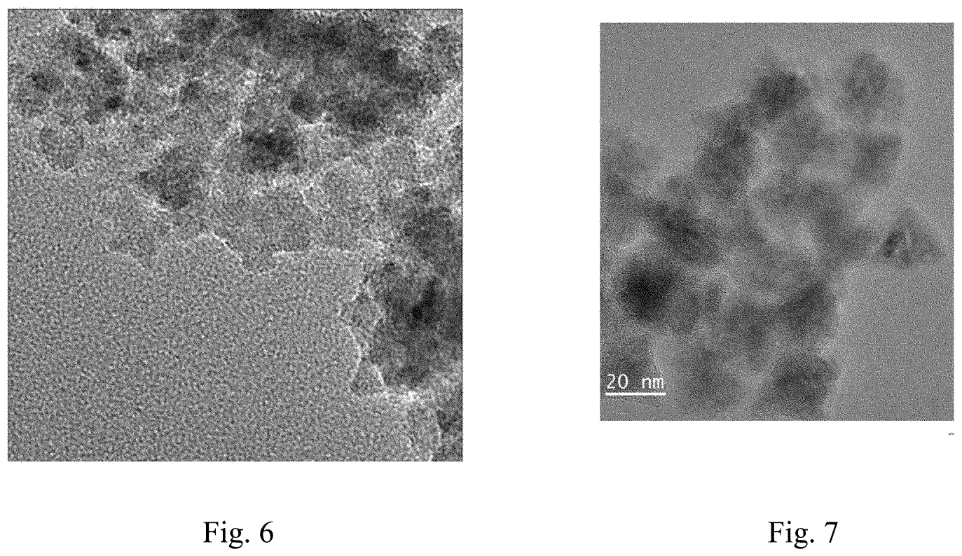

In operation 230, the wavelength conversion materials are grinded. Mechanical grinding may be used to grind the wavelength conversion materials 100a. For example, centrifugal grinding, vibration grinding, or the like may be used to grind the wavelength conversion materials 100a. During grinding, the wavelength conversion materials 100a are grinded into a plurality of smaller wavelength conversion materials 100b. Further, because oxygen groups (O—) and hydroxide groups (OH—) dissociated from phosphates and alcohol functional groups in the specific mixtures may bond with surfaces of the covering layer 120, this bonding assists to grind the wavelength conversion materials 100a into wavelength conversion materials 100b (100c, 100d and/or 100e) including single or few luminous cores 110. The experiment results show (as shown in FIG. 6 and FIG. 7) that using the additives discussed above may generate sharp corners 122 on the outer surfaces 124, as shown in FIG. 1B to FIG. 1E.

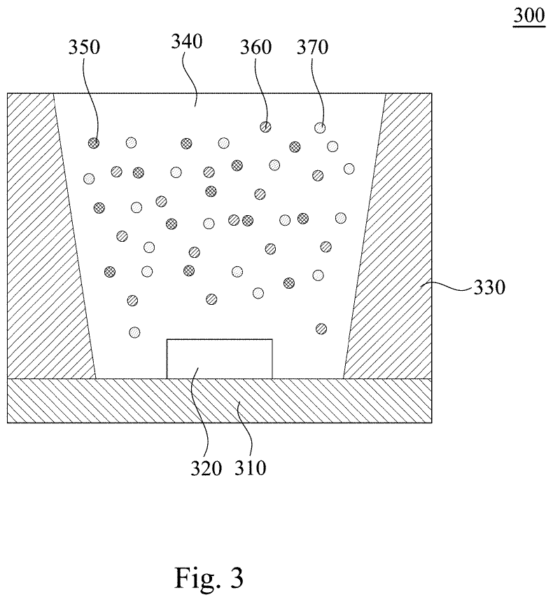

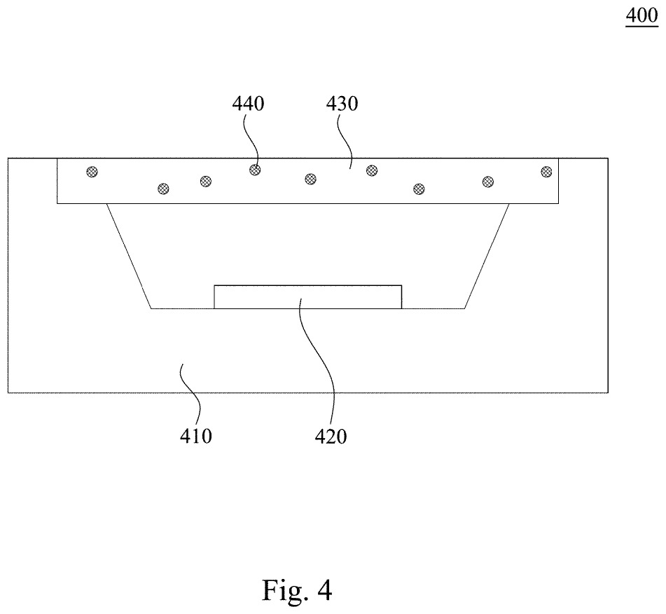

In operation 240, the wavelength conversion materials are dried. After grinding, the grinded wavelength conversion materials 100b (100c, 100d and/or 100e) may be dried to remove additives in the wavelength conversion materials 100b (100c, 100d and/or 100e), such that additives do not exist in the wavelength conversion materials 100b (100c, 100d and/or 100e) to affect subsequent processes. In operation 250, subsequent applications of the wavelength conversion materials are performed. For example, the wavelength conversion materials 100b (100c, 100d and/or 100e) may be applied in the adhesive materials or the plate materials of LED. Specific embodiments are referred in FIG. 3 and FIG. 4 in the following description.

FIG. 3 illustrates a light-emitting device 300 using the wavelength conversion materials in accordance with some embodiments of the present disclosure. The light-emitting device 300 may include a substrate 310, a LED 320, sidewalls 330, an adhesive material 340, wavelength conversion materials 350, 360 and 370. The substrate 310 may include a circuit board and a conductive layer disposed thereon. Although FIG. 3 illustrates substrate 310 is in a plate-shape, the shape of the substrate 310 is not limited. In some embodiments, the substrate 310 may be in other shapes, such as cup-shape. The LED 320 may be disposed on the substrate 310 and electrically connected to the circuit board through the conductive layer. The LEDs 320 may emit light with a specific wavelength, such as blue light or ultraviolet light, etc. This light may be guided by the sidewalls surrounding the LED 320 to emit in desired direction. The adhesive material 340 is a transparent material and is filled around the LED 320 and in a space defined by the sidewalls 330. The wavelength conversion materials 350, 360 and 370 are dispersed in the adhesive material 340 to convert the wavelength of the light emitted from the LEDs 320. For example, the wavelength conversion materials 350, 360 and 370 may be used to convert blue light emitted from the LED 320 to light with other wavelengths (such as green light or red light). Each of the wavelength conversion materials 350, 360 and/or 370 has a structure as shown in one of FIGS. 1B-1E. The difference between the wavelength conversion materials 350, 360 and 370 is the material of the luminous core 110 (as shown in FIG. 1B), such that the wavelength conversion materials 350, 360 and 370 may emit different lights. Although the light-emitting device 300 includes three kinds of the wavelength conversion materials 350, 360 and 370 in FIG. 3, the light-emitting device 300 may include only one, two or more than three types of the wavelength conversion materials in other embodiments, which is not limited in the present disclosure.

FIG. 4 illustrates a light-emitting device 400 using the wavelength conversion materials in accordance with some embodiments of the present disclosure. The light-emitting device 400 may include a base 410, a LED 420, a plate 430 and wavelength conversion materials 440. The base 410 may have a recess, and the bottom portion of the recess has circuits. The LED 420 may be disposed in the recess of the base 410 and is electrically connected to the circuits of the base 410 to emit light with the specific wavelength, such as blue light or UV light. The plate 430 covers the LED and entirely covers the recess of the base 410. The plate 430 may be made of any suitable transparent materials, such as glass, quartz, plastics or the like. The wavelength conversion materials 440 are dispersed in the plate 430 to convert the wavelength of the light emitted from the LED 420. For example, the wavelength conversion materials 440 may be used to convert blue light emitted from the LED 420 to light with other wavelengths (such as green light or red light). The space between the plate 430 and the LED 420, the recess of the base 410 may be a vacuum or be filled with any suitable materials, such as gas, liquid, adhesive or the like. The wavelength conversion materials 440 have the structures as shown in one of FIGS. 1B-1E. Although the light-emitting device 400 includes one kind of the wavelength conversion materials 440 in FIG. 4, the light-emitting device 400 may include two or more than two types of the wavelength conversion materials in other embodiments, which is not limited in the present disclosure.

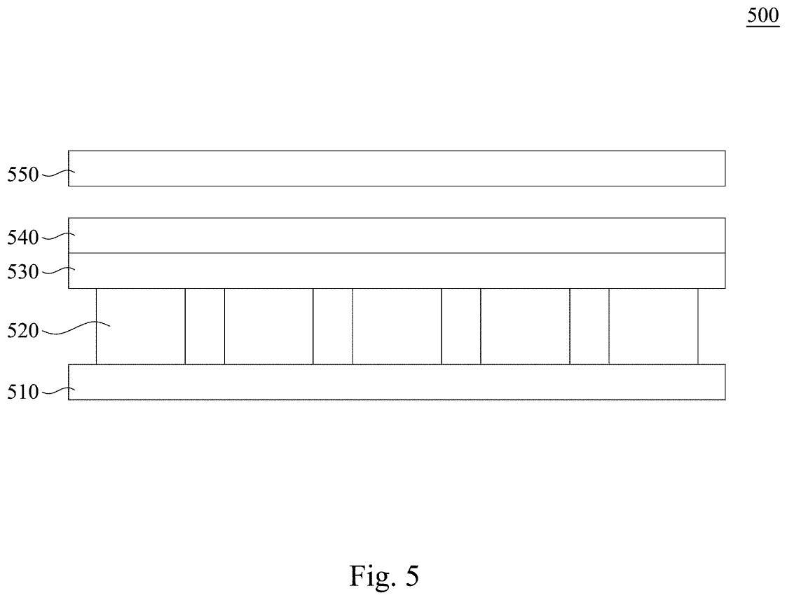

FIG. 5 illustrates a display device 500 using the wavelength conversion materials in accordance with some embodiments of the present disclosure. The display device 500 may include a carrier substrate 510, light-emitting devices 520, an optical film 530, a diffusion film 540 and a panel 550.

The light-emitting devices 520 may be arranged on the carrier substrate 510 and serve as backlight sources of white light. The carrier substrate 510 may be a circuit board. The light-emitting devices 520 may be in the forms of the light-emitting device 300 in FIG. 3, the light-emitting device 400 in FIG. 4 or other suitable configurations. In some embodiments, the light-emitting devices 520 include the LED 320 or 420 which are able to emit the blue light and wavelength conversion materials which are able to convert the blue light to the green or red light after absorbing the blue light. The red light, the green light and the blue light become the white light after mixing. In some other embodiments, the light-emitting devices 520 include the LED 320 or 420 which are able to emit the blue light and wavelength conversion materials which are able to convert the blue light to yellow light after absorbing the blue light. The yellow light and the blue light become the white light after mixing.

The optical film 530 is disposed over the light-emitting devices 520. In some embodiments, the optical film 530 may include a prism film and a brightness enhancement film. It is noted that although FIG. 5 illustrates one optical film 530, the number of the optical film 530 may be more, such as two or more. The main function of the optical film 530 is to converge light, increase front light and improve brightness by refraction and reflection of light. When the light is diffused from the light-emitting devices 520, the light is not concentrated and the directivity is poor. The overall brightness of the display device 500 may be much significantly improved by adjusting the direction of the light with the optical film 530.

The diffusion film 540 is disposed on the optical film 530. The diffusion film 540 may be used to improve distribution of the light to broaden the vision. The diffusion film 540 may also make the light emitted from the subsequently formed panel 550 evener, thereby resulting in a soft and even surface light source of the display device 500.

The panel 550 is disposed over the diffusion film 540. In some embodiments, the panel may be a liquid crystal panel. In some other embodiments, the display device 500 may further include other optical components to enhance the visual performance of the display device 500.

FIGS. 6-7 illustrate TEM (Transmission Electron Microscopy) images of the grinded wavelength conversion materials under different magnifications in accordance with some embodiments of the present disclosure. In FIGS. 6-7, the outer surface of the wavelength conversion materials is observed by TEM. Multiple sharp corners are observed on the outer surface, and these sharp corners are obtained by using the additives as discussed before when grinding the wavelength conversion materials.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A wavelength conversion material, comprising:
a luminous core comprising a quantum dot or a fluorescent powder; and
a covering layer covering the luminous core, wherein the covering layer is an amorphous material, and an outer surface of the covering layer has at least one sharp corner.

2. The wavelength conversion material of claim 1, wherein the amorphous material is a dielectric material.

3. The wavelength conversion material of claim 1, wherein the covering layer is a non-luminous material.

4. The wavelength conversion material of claim 1, wherein the covering layer is a non-metal material.

5. The wavelength conversion material of claim 1, wherein the covering layer is an integrally-formed structure.

6. The wavelength conversion material of claim 1, wherein the covering layer is substantially transparent.

7. The wavelength conversion material of claim 1, wherein the outer surface of the covering layer further comprises a first concave portion and a second concave portion, the first concave portion and the second concave portion together defining the sharp corner.

8. The wavelength conversion material of claim 1, wherein a diameter of the luminous core is in a range from 15 nm to 25 nm.

9. A light-emitting device, comprising:
a substrate;
a light-emitting diode on the substrate;
a transparent material covering the light-emitting diode; and
a plurality of the wavelength conversion materials of claim 1 dispersed in the transparent material.

10. A display device, comprising:
a carrier substrate; and
a plurality of the light-emitting devices of claim 9 arranged on the carrier substrate.
